(19) United States
(12) Patent Application Publication
(10) Pub. No.: US 2014/0281284 A1
(43) Pub. Date: Sep. 18, 2014

(54) MULTI-READ PORT MEMORY

(71) Applicant: LSI Corporation, San Jose, CA (US)

(72) Inventors: Stefan G. Block, Munich (DE); Ting Zhou, Orinda, CA (US); Mikhail I. Grinchuk, San Jose, CA (US); Anatoli A. Bolotov, San Jose, CA (US); Lav D. Ivanovic, Sunnyvale, CA (US)

(21) Appl. No.: 13/833,691

(22) Filed: Mar. 15, 2013

Related U.S. Application Data
(60) Provisional application No. 61/779,017, filed on Mar. 13, 2013.

(51) Int. Cl. G11C 7/10

(52) U.S. Cl. CPC G11C 7/1075
USPC 711/149

(57) ABSTRACT

A method includes receiving a multi-port read request for retrieval of data stored in three memories, each comprising two memory modules and a parity module. The multi-port read request is associated with first data stored at a first memory address, second data stored at a second memory address, and third data stored at a third memory address. When the first memory address, the second memory address, and the third memory address are associated with a first memory module, first data is retrieved from the first memory module, second data is reconstructed using data from a second memory module and a first parity module, and third data is reconstructed using data from a fourth memory module and a seventh memory module. The first data, the second data, and the third data are provided in response to the multi-port read request.

### CROSS-REFERENCE TO RELATED APPLICATIONS

The present application claims the benefit under 35 U.S.C. §119(e) of U.S. Provisional Application Ser. No. 61/779,017, filed Mar. 13, 2013, and titled “MULTI-READ PORT MEMORY,” which is herein incorporated by reference in its entirety.

### FIELD OF THE INVENTION

The present disclosure is related to systems and techniques for implementing a multi-read port memory.

### BACKGROUND

In some instances, it is desirable to provide memory, such as random-access memory (RAM), with more than one read port. One technique is to increase the clock speed of the memory. For example, by doubling the clock speed of RAM with respect to the functional clock speed of a computing system connected to the RAM, a one-port RAM can be accessed twice per functional clock cycle, behaving as a two-port RAM with respect to the functional clock speed. Correspondingly, by multiplying the clock speed of RAM by four, a one-port RAM can be implemented as a four-port RAM. However, each RAM has a maximum speed of operation, which can limit the number of read ports attainable with this technique with respect a desired functional clock speed. Further, dynamic power doubles when clock speed is doubled, and latency is often added to the system when data-interfaces between a lower system clock speed and the high speed RAM clock are introduced. Another technique for increasing the number of read ports is to duplicate the RAM instances. However, this requires area duplication, as well as duplication of static RAM power, and an increase in dynamic power. A further technique is to provide a custom multi-port memory. However, for a multi-port memory with multi-port bit cells and multiple read bit lines, additional test chips are required, as well as more area with increased power consumption.

### SUMMARY

A method includes receiving a multi-port read request for retrieval of data stored in a first memory comprising two memory modules and a parity module, a second memory comprising two memory modules and a parity module, and a third memory comprising two memory modules and a parity module. The multi-port read request is associated with first data stored at a first memory address associated with a first port, second data stored at a second memory address associated with a second port, and third data stored at a third memory address associated with a third port. When the first memory address, the second memory address, and the third memory address are associated with a first memory module, first data is retrieved from the first memory module, second data is reconstructed using data from a second memory module and a first parity module, and third data is reconstructed using data from a fourth memory module and a seventh memory module. The first data, the second data, and the third data are provided in response to the multi-port read request.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE FIGURES

Other embodiments of the disclosure will become apparent.

FIG. 1 is a block diagram illustrating a memory with two (2) read ports in accordance with an example embodiment of the present disclosure.

FIG. 2 is a block diagram illustrating a memory with three (3) read ports in accordance with an example embodiment of the present disclosure.

FIG. 3 is a block diagram illustrating a memory with four (4) read ports in accordance with an example embodiment of the present disclosure.

FIG. 4 is a block diagram illustrating a memory with two (2) read ports in accordance with another example embodiment of the present disclosure.

FIG. 5 is a block diagram illustrating a memory with four (4) read ports in accordance with another example embodiment of the present disclosure.

FIG. 6 is a block diagram illustrating a memory with eight (8) read ports in accordance with an example embodiment of the present disclosure.

FIG. 7 is a block diagram illustrating a memory with two (2) read ports in accordance with a further example embodiment of the present disclosure.

FIG. 8 is a block diagram illustrating a memory with four (4) read ports in accordance with a further example embodiment of the present disclosure.

FIG. 9 is a block diagram illustrating a memory with two (2) multi-port memory arrays, where a first multi-port memory array is operated in a read configuration, and a second multi-port memory array is operated in a write configuration in accordance with an example embodiment of the present disclosure.

FIG. 10 is a block diagram illustrating a system including a controller operatively coupled with a memory in accordance with an example embodiment of the present disclosure.

### DETAILED DESCRIPTION

Referring to FIG. 1, a memory 100 with two (2) read ports is described. The memory 100 includes a number of memory modules. In embodiments of the disclosure, each memory module is configured as a random-access memory (RAM) building block having a single read/write port (1rw RAM). The read word for memory 100 has n-bits, and the write word for memory 100 has m*n-bits. The memory 100 includes m+1 instances of the memory modules. In the present example, memory 100 includes a memory module 102, a memory module 104, a memory module 106, a memory module 108, and a memory module configured as a parity module 110. Memory module 102 stores a sub-word A, memory module 104 stores a sub-word B, memory module 106 stores a sub-word C, and memory module 108 stores a sub-word D. In this embodiment, a parity sub-word P is determined by a bitwise exclusive or (XOR) operation on the different sub-words. The parity module 110 stores the parity P=ÂB̂ĈD, where the character “̂” represents the bitwise XOR operation.

In a case where two (2) sub-words are read from different memory modules, each sub-word is read from each memory module. However, in a case where two (2) sub-words are read from the same memory module, a first read address port reads from the target memory module (e.g., from memory module 102), while a second read address port reads from the other memory modules and the parity module (e.g., from memory modules 104, 106, and 108 and from parity module 110) and an XOR operation is performed on the data. In this example, B̂ĈD̂P=B̂ĈD̂(ÂB̂ĈD)=ÂB̂B̂ĈĈD̂D=A. In this manner, the memory modules and the parity module are used to build a two (2) read port memory using, for example, single read port building blocks. Thus, the memory 100 can support two (2) reads or one (1) write at any given time.

Referring to FIG. 2, a memory 200 with three (3) read ports is described. The memory 200 includes a memory module 202, a memory module 204, a memory module 206, a memory module 208, a memory module configured as a parity module 210, a memory module configured as a parity module 212, a memory module configured as a parity module 214, and a memory module configured as a parity module 216. Memory module 202 stores a sub-word A, memory module 204 stores a sub-word B, memory module 206 stores a sub-word C, and memory module 208 stores a sub-word D. Parity module 210 stores a parity P1=ÂB. Parity module 212 stores a parity P2=ĈD. Parity module 214 stores a parity P3=ÂC. Parity module 216 stores a parity P4=B̂D.

In a case where three (3) sub-words are read from different memory modules, each sub-word is read from each memory module. In a case where three (3) sub-words are read from a single memory module, a first read address port reads from the target memory module (e.g., from memory module 202). A second read address port reads from the other memory modules of the same row including the parity module (e.g., memory module 204 and parity module 210), and an XOR operation is performed on the data. In this example, (B̂P1)=B̂(ÂB)=ÂB̂B=A. A third read address port reads from the other memory modules of the same column including the parity module (e.g., memory module 206 and parity module 214), and an XOR operation is performed on the data. In this example, (ĈP3)=Ĉ(ÂC)=ÂĈC=A.

In a case where two (2) sub-words are read from the same memory module, and one (1) sub-word is read from a different memory module, a first read address port reads from the first target memory module (e.g., from memory module 202). A second read address port reads from the second target memory module (e.g., from memory module 204). Then, if a third read address port is to be read from the first target memory module, a determination is made as to whether the second read address port was read from the same row as the first read address port. If not, all other memory modules in the same row including the parity module are read (e.g., memory module 204 and parity module 210), and an XOR operation is performed on the data (e.g., (B̂P1)=B̂(ÂB)=ÂB̂B=A). Otherwise, as in the present example, if the second read address port was read from the same row as the first read address port, all other memory modules in the same column including the parity module are read (e.g., memory module 206 and parity module 214), and an XOR operation is performed on the data. In this example, (ĈP3)=Ĉ(ÂC)=ÂĈC=A. In this manner, the memory modules and the parity modules are used to build a three (3) read port memory using, for example, single read port building blocks. Thus, the memory 200 can support three (3) reads or one (1) write at any given time.

Referring to FIG. 3, a memory 300 with four (4) read ports is described. The memory 300 includes a memory module 302, a memory module 304, a memory module 306, a memory module 308, a memory module configured as a parity module 310, a memory module configured as a parity module 312, a memory module configured as a parity module 314, a memory module configured as a parity module 316, and a memory module configured as a parity module 318. Memory module 302 stores a sub-word A, memory module 304 stores a sub-word B, memory module 306 stores a sub-word C, and memory module 308 stores a sub-word D. Parity module 310 stores a parity P1=ÂB. Parity module 312 stores a parity P2=ĈD. Parity module 314 stores a parity P3=ÂC. Parity module 316 stores a parity P4=B̂D. Parity module 318 stores a parity P5=ÂB̂ĈD=P1̂P2=P3̂P4.

In a case where four (4) sub-words are read from different memory modules, each sub-word is read from each memory module. In a case where four (4) sub-words are read from a single memory module, a first read address port reads from the target memory module (e.g., from memory module 302). A second read address port reads from the other memory modules of the same row including the parity module (e.g., memory module 304 and parity module 310), and an XOR operation is performed on the data. In this example, (B̂P1)=B̂(ÂB)=ÂB̂B=A. A third read address port reads from the other memory modules of the same column including the parity module (e.g., memory module 306 and parity module 314), and an XOR operation is performed on the data. In this example, (ĈP3)=Ĉ(ÂC)=ÂĈC=A. A fourth read address port reads from the other memory modules that do not belong to the same row or column (e.g., memory module 308, parity module 312, parity module 316, and parity module 318), and an XOR operation is performed on the data. In this example, (D̂P2̂P4̂P5)=D̂(ĈD)̂(B̂D)̂(ÂB̂ĈD)=Â(B̂B)̂(ĈC)̂(D̂D̂D̂D)=A.

In an example where two (2) sub-words are read from the same memory module, and two (2) sub-words are read from two other, different memory modules, a first read address port reads from the first target memory module (e.g., from memory module 302). A second read address port reads from the second target memory module (e.g., from memory module 304). Then, if a third read address port is to be read from the first target memory module, all other memory modules in the same column including the parity module are read (e.g., memory module 306 and parity module 314), and an XOR operation is performed on the data. In this example, (ĈP3)=Ĉ(Âc)=ÂĈC=A. Then, a fourth read address port reads from a third target memory module (e.g., memory module 308).

In an example where two (2) sub-words are read from the same memory module, and two (2) sub-words are read from a single other memory module, a first read address port reads from the first target memory module (e.g., from memory module 302). A second read address port reads from the second target memory module (e.g., from memory module 304). Then, if a third read address port is to be read from the first target memory module, all other memory modules in the same column including the parity module are read (e.g., memory module 306 and parity module 314), and an XOR operation is performed on the data. In this example, (ĈP3)=Ĉ(ÂC)=ÂĈC=A. Then, if a fourth read address port is to be read from the second target memory module, all other memory modules in the same column including the parity module are read (e.g., memory module 308 and parity module 316), and an XOR operation is performed on the data (e.g., (D̂P4)=D̂(B̂D)=B̂D̂D=B).

In an example where three (3) sub-words are read from the same memory module, and one (1) sub-word is read from a different memory module, a first read address port reads from the first target memory module (e.g., from memory module 302). A second read address port reads from the second target memory module (e.g., from memory module 304). Then, if a third read address port is to be read from the first target memory module, all other memory modules in the same column including the parity module are read (e.g., memory module 306 and parity module 314), and an XOR operation is performed on the data. In this example, (ĈP3)=Ĉ(ÂC)=ÂĈC=A. Then, if a fourth read address port is to be read from the first target memory module, the other memory modules that do not belong to the same row or column are read (e.g., memory module 308, parity module 312, parity module 316, and parity module 318), and an XOR operation is performed on the data. In this example, (D̂P2̂P4̂P5)=D̂(ĈD)̂(B̂D)̂(ÂB̂ĈD)=Â(B̂B)̂(ĈC)̂(D̂D̂D̂D)=A. In this manner, the memory modules and the parity modules are used to build a four (4) read port memory using, for example, single read port building blocks. Thus, the memory 300 can support four (4) reads or one (1) write at any given time.

Referring now to FIG. 4, a memory 400 with two (2) read ports is described. The memory 400 includes a number of memory modules. The memory 400 includes a memory module 402, a memory module 404, and a memory module configured as a parity module 406. Memory module 402 stores a sub-word A, and memory module 404 stores a sub-word B. Parity module 408 stores a parity P1=ÂB. In a case where two (2) sub-words are read from different memory modules, each sub-word is read from each memory module. However, in a case where two (2) sub-words are read from the same memory module, a first read address port reads from the target memory module (e.g., from memory module 402), while a second read address port reads from the other memory module and the parity module (e.g., from memory module 404 and from parity module 406) and an XOR operation is performed on the data. In this example, B̂P=B̂(ÂB)=ÂB̂B=A. In this manner, the memory modules and the parity module are used to build a two (2) read port memory using, for example, single read port building blocks. Thus, the memory 400 can support two (2) reads or one (1) write at any given time.

Referring to FIG. 5, a memory 500 with four (4) read ports is described. The memory 500 includes multiple memory modules. The memory 500 includes a first memory 400 with a memory module A, a memory module B, and a memory module configured as a parity module P1; a second memory 400 with a memory module C, a memory module D, and a memory module configured as a parity module P2; and a third memory 400 with a memory module P3, a memory module P4, and a memory module configured as a parity module P5. As shown, memory module A stores a sub-word A, memory module B stores a sub-word B, memory module C stores a sub-word C, and memory module D stores a sub-word D. As discussed with reference to FIG. 4, each of the memory modules 400 functions as a 2-read port RAM (2RPRAM). Parity module P1 stores a parity P1=ÂB. Parity module P2 stores a parity P2=ĈD. Parity module P3 stores a parity P3=ÂC. Parity module P4 stores a parity P4=B̂D. Parity module P5 stores a parity P5=P3̂P4=ÂB̂ĈD.

In a case where two (2) sub-words are read from different memories 400, each sub-word is read from each memory 400. However, in a case where two (2) sub-words are read from the same memory 400, a first read address port reads from the target memory (e.g., from first memory 400), while a second read address port reads from the other memories 400 (e.g., from second memory 400 and third memory 400) and an XOR operation is performed on the data. Then, where two (2) more sub-words are read from different memories 400, each sub-word is read from each memory 400. However, in a case where the two (2) additional sub-words are read from the same memory 400, a third read address port reads from the target memory (e.g., from first memory 400), while a fourth read address port reads from the other memories 400 (e.g., from second memory 400 and third memory 400) and an XOR operation is performed on the data.

For example, if all four read address ports are to be read from memory module A, the addresses for first and second read address ports are compared and found to be targeting the same memory 400. In this example, the first read address port reads from the target memory (e.g., from first memory 400), while the second read address port reads from the other memories 400 (e.g., from second memory 400 and third memory 400) and an XOR operation is performed on the data. Then, when the addresses for third and fourth read address ports are compared and found to be targeting the same first memory 400, the third read address port reads from the target memory (e.g., first memory 400), while the fourth read address port reads from the other memories 400 (e.g., from second memory 400 and third memory 400) and an XOR operation is performed on the data.

With more specificity, when the first read address port and the third read address port each read from the first memory 400, the first read address port reads memory module A. The third read address port reads memory modules B and P1, and an XOR operation is performed on the data (e.g., B XOR P1=A). When the second read address port and the fourth read address port each read from the second and third memories 400, the second read address port reads memory modules C and P3, and an XOR operation is performed on the data (e.g., C XOR P3=A). The fourth read address port reads memory modules D, P2, P4, and P5, and an XOR operation is performed on the data (e.g., D XOR P2 XOR (P4 XOR P5)=A). In this manner, all four read-ports are read from the same memory module.

It should be noted that the configuration described with reference to FIG. 5 is provided by way of example only and is not meant to limit the present disclosure. For example, in embodiments of the disclosure, one or more of the memories 400 is implemented as a memory 100 (FIG. 1), a memory 200 (FIG. 2), a memory 300 (FIG. 3), a memory 400 (FIG. 4), a memory 700 (FIG. 7), and so forth. Further, while FIG. 5 illustrates first, second, and third memories 400, it should be noted that more than three memories can be provided. For example, in some implementations, five (5) memories 400 (e.g., with one memory 400 configured as parity) are provided (e.g., in the manner of memory 100 of FIG. 1). In other embodiments, eight (8) memories 400 (e.g., with four memories 400 configured as parity) are provided (e.g., in the manner of memory 200 of FIG. 2). In still further embodiments, nine (9) memories 400 (e.g., with five memories 400 configured as parity are provided (e.g., in the manner of memory 300 of FIG. 3).

Further, it should be noted that additional parity modules can be added to an array of parity modules to further increase the number of read ports. For example, with reference to FIG. 6, a memory 600 with eight (8) read ports is described. The memory 600 includes four (4) memories 500 with four (4) read ports each (e.g., as discussed with reference to FIG. 5), where each memory 500 includes three (3) memories 400 (one or more of which is implemented as a memory 100 (FIG. 1), a memory 200 (FIG. 2), a memory 300 (FIG. 3), a memory 400 (FIG. 4), a memory 700 (FIG. 7), and so forth) with two (2) read ports each (e.g., as discussed with reference to FIG. 4). Thus, by staging memory modules configured as parity modules inside of parity modules, an eight (8) read-port memory can be built from memory modules configured as, for example, RAM building blocks each having a single read/write port. Using the techniques described herein, a memory with sixty-four (64) read ports is constructed, where each read port has thirty-two (32) bits, and the write port has six thousand one hundred and forty-four (6,144) bits. In this example, the basic building block is a single-port memory module with eighty (80) words and thirty-two (32) bits.

For example, three (3) (two (2) data and one (1) parity) single-port memory modules with eighty words (80) and thirty-two (32) bits are used to provide a memory with two (2) read ports with thirty-two (32) bits each, and one (1) write port with sixty-four (64) bits. Then, three (3) (two (2) data and one (1) parity) two (2) read port memories as described are used to provide a memory with four (4) read ports with thirty-two (32) bits each, and one (1) write port with one hundred and twenty-eight (128) bits. Next, three (3) (two (2) data and one (1) parity) four (4) read port memories as described are used to provide a memory with eight (8) read ports with thirty-two (32) bits each, and one (1) write port with two hundred and fifty-six (256) bits. Then, three (3) (two (2) data and one (1) parity) eight (8) read port memories as described are used to provide a memory with sixteen (16) read ports with thirty-two (32) bits each, and one (1) write port with five hundred and twelve (512) bits. Next, five (5) (four (4) data and one (1) parity) sixteen (16) read port memories as described are used to provide a memory with thirty-two (32) read ports with thirty-two (32) bits each, and one (1) write port with two thousand and forty-eight (2,048) bits. Then, four (4) (three (3) data and one (1) parity) thirty-two (32) read port memories as described are used to provide a memory with sixty-four (64) read ports with thirty-two (32) bits each, and one (1) write port with six thousand one hundred and forty-four (6,144) bits.

In this example, 3*3*3*3*5*4=1,620 single-port memory modules with eighty words (80) and thirty-two (32) bits are used to provide a sixty-four (64) read port memory. It should be noted that with typical memory duplication techniques, 192*64=12,288 single-port memory modules with eighty words (80) and thirty-two (32) bits would otherwise be required to provide a sixty-four (64) read port memory. Thus, techniques in accordance with the present disclosure provide significant area and power savings (e.g., with respect to typical memory duplication techniques).

In embodiments of the disclosure, a memory having multiple read-ports is constructed from single-port memory modules using parity. For example, if a desired multi-port memory has read-ports with the same number of bits as a write word, but the memory uses sequential write operations (e.g., where the memory is always written to from a base address (e.g., address 0) to a maximum address before a subsequent read operation), and read and write operations are not performed simultaneously, a parity register is used to write to the multiple read-port memory. Further, if the memory does not use sequential write operations, write operations can be performed by not only writes to the target memory but also by reading back the rest of the data memories and updating the parity memories. For instance, using memory 500 as an example, when writing to A, the rest of data memories B, C, and D are read, and parity is recomputed using the new data in A and the existing data in B, C, and D to update P1, P2, P3, P4 and P5.

Referring now to FIG. 7, a memory 700 with two (2) read ports is described. The memory 700 includes a number of memory modules and a parity register. The memory 700 includes a memory module RAMA, a memory module RAMB, a memory module configured as a parity module RAMP, and a parity register P_reg. In the present example, memory 700 supports three hundred and twenty (320) words and two (2) thirty-two (32) bit read ports and is constructed using two (2) single-port memory modules, each with one hundred and sixty (160) words and a thirty-two (32) bit read port (e.g., memory modules RAMA and RAMB), and a single-port memory module configured as a parity module with one hundred and sixty (160) words and a thirty-two (32) bit read port (e.g., parity module RAMP). In this example, a write operation is performed as follows:

1. Write to address 0:
write din into address 0 of memory module RAMA
store din in parity register P_reg

2. Write to address 1:
write din into address 0 of memory module RAMB
write din XOR parity register P_reg into address 0 of parity module RAMP

3. Write to address 2:
write din into address 1 of memory module RAMA
store din in parity register P_reg

In this manner, data associated with even memory addresses is stored in memory module RAMA and data associated with odd memory addresses is stored in memory module RAMB. In this example, a read operation is performed as follows:

| LSB | LSB | | |
|---|---|---|---|
| Read | Read | Port1 | Port2 |
| port 1 | port2 | reads | reads |
| 0 | 0 | RAMA | RAMB \hat{ } RAMP |
| 0 | 1 | RAMA | RAMB |
| 1 | 0 | RAMB | RAMA |
| 1 | 1 | RAMB | RAMA \hat{ } RAMP |

In another example, a memory with four (4) read ports is described. In the present example, the memory supports three hundred and twenty (320) words and four (4) thirty-two (32) bit read ports and is constructed using four (4) single-port memory modules RAMA, RAMB, RAMC, and RAMD, each with eighty (80) words and a thirty-two (32) bit read port, and a single-port memory module configured as a parity module RAMP with eighty (80) words and a thirty-two (32) bit read port. The memory also includes a parity register P_reg. In this example, a write operation is performed as follows:

1. Write to address 0:
write din into address 0 of memory module RAMA
store din in parity register P_reg

2. Write to address 1:
write din into address 0 of memory module RAMB
write din XOR parity register P_reg into parity register P_reg

3. Write to address 2:
write din into address 0 of memory module RAMC
write din XOR parity register P_reg into parity register P_reg

4. Write to address 3:
write din into address 0 of memory module RAMD
store din in parity register P_reg
write din XOR parity register P_reg into address 0 of parity module RAMP

5. Write to address 4:
write din into address 1 of memory module RAMA
store din in parity register P_reg

and so forth

Further, in this example, a read operation is performed as follows:

| LSBs | LSBs | | |
|---|---|---|---|
| Read | Read | Port1 | Port2 |
| port1 | port2 | reads | reads |
| 00 | 00 | RAMA | RAMB \hat{ } RAMC \hat{ } RAMD \hat{ } RAMP |
| 00 | 01 | RAMA | RAMB |
| 00 | 10 | RAMA | RAMC |
| 00 | 11 | RAMA | RAMD |
| 01 | 00 | RAMB | RAMA |
| 01 | 01 | RAMB | RAMA \hat{ } RAMC \hat{ } RAMD \hat{ } RAMP |
| 01 | 10 | RAMB | RAMC |
| 01 | 11 | RAMB | RAMD |
| 10 | 00 | RAMC | RAMA |
| 10 | 01 | RAMC | RAMB |
| 10 | 10 | RAMC | RAMA \hat{ } RAMB \hat{ } RAMD \hat{ } RAMP |
| 10 | 11 | RAMC | RAMD |
| 11 | 00 | RAMD | RAMA |
| 11 | 01 | RAMD | RAMB |
| 11 | 10 | RAMD | RAMC |
| 11 | 11 | RAMD | RAM \hat{ } RAMB \hat{ } RAMC \hat{ } RAMP |

Referring now to FIG. 8, a memory 800 with four (4) read ports is described. The memory 800 includes a number of memory modules and a parity register. For example, the memory 800 includes three (3) memories 700 (one or more of which is implemented as a memory 100 (FIG. 1), a memory 200 (FIG. 2), a memory 300 (FIG. 3), a memory 400 (FIG. 4), a memory 700 (FIG. 7), and so forth, where one or more of the memories 100, 200, 300, 400, or 700 includes one or more parity registers). The memory 800 includes a memory RAM AB 700 with a memory module RAMA, a memory module RAMB, a memory module configured as a parity module RAMP1, and a parity register P_reg AB; a memory RAM CD 700 with a memory module RAMC, a memory module RAMD, a memory module configured as a parity module RAMP2, a parity register P_reg CD; a memory RAM P 700 with a memory module RAMP3, a memory module RAMP4, a memory module configured as a parity module RAMP5, and a parity register P_reg P3P4; and a parity register 802. In this example, a write operation is performed as follows:

1. Write to address 0:
store din in parity register 802
write din into address 0 of memory RAM AB 700
   store din in parity register P_reg AB
   write din into address 0 of memory module RAMA

2. Write to address 1:
write din into address 0 of memory RAM CD 700
   store din in parity register P_reg CD
   write din into address 0 of memory module RAMC
write din XOR parity register 802 into address 0 of memory RAM P 700
   store din XOR parity register 802 in parity register P_reg P3P4
   write din XOR parity register 802 into address 0 of memory module RAMP3

3. Write to address 2:
store din in parity register 802
write din into address 0 of memory RAM AB 700
   write din into address 0 of memory module RAMB
   write din XOR parity register P_reg AB into address 0 of parity module RAMP1

4. Write to address 3:
write din into address 0 of memory RAM CD 700
   write din into address 0 of memory module RAMD
   write din XOR parity register P_reg CD in parity module RAMP2
write din XOR parity register 802 into address 0 of memory RAM P 700
write din XOR parity register 802 into address 0 of memory module RAMP4
write din XOR parity register 802 XOR memory RAM P 700 into address 0 of parity module RAMP5

and so forth

With reference to the memory modules RAMA, RAMB, RAMC, RAMD, RAMP3, RAMP4, and parity modules RAMP1, RAMP2, and RAMP5, the original addresses are mapped as follows:

| RAMA | RAMB | RAMP1 | RAMC | RAMD | RAMP2 | RAMP3 | RAMP4 | RAMPS |
|---|---|---|---|---|---|---|---|---|
| 0 | 2 | 0\hat{ }2 | 1 | 3 | 1\hat{ }3 | 0\hat{ }1 | 2\hat{ }3 | 0\hat{ }1\hat{ }2\hat{ }3 |
| A | B | A\hat{ }B | C | D | C\hat{ }D | A\hat{ }C | B\hat{ }D | A\hat{ }B\hat{ }C\hat{ }D |
| 4 | 6 | 4\hat{ }6 | 5 | 7 | 5\hat{ }7 | 4\hat{ }5 | 6\hat{ }7 | 4\hat{ }5\hat{ }6\hat{ }7 |
| A | B | A\hat{ }B | C | D | C\hat{ }D | A\hat{ }C | B\hat{ }D | A\hat{ }B\hat{ }C\hat{ }D |

Further, in this example, a read operation is performed as follows:

| LSBs | LSBs | LSBs | LSBs | | | | |
|---|---|---|---|---|---|---|---|
| Read | Read | Read | Read | Port 1 | Port2 | Port3 | Port4 |
| port1 | port2 | port3 | port4 | reads | reads | reads | reads |
| 00 | 00 | 00 | 00 | RAMA | RAMB\hat{ }RAMP1 | RAMC\hat{ }RAMP3 | RAMD\hat{ }RAMP2\hat{ }RAM4\hat{ }RAMP5 |
| | | | | = A | = B\hat{ }(A\hat{ }B) | = C\hat{ }(A\hat{ }C) | = D\hat{ }(C\hat{ }D)\hat{ }(B\hat{ }D)\hat{ }(A\hat{ }B\hat{ }C\hat{ }D) |
| | | | | | = A | = A | = A |
| 00 | 00 | 00 | 01 | RAMA | RAMB\hat{ }RAMP1 | RAMC | RAMD\hat{ }RAMP2\hat{ }RAMP3 |
| | | | | | = B\hat{ }(A\hat{ }B) | | = D\hat{ }(C\hat{ }D)\hat{ }(A\hat{ }C) |
| | | | | | = A | | = A |
| : | : | : | : | | | | |
| 00 | 01 | 10 | 11 | RAMA | RAMC | RAMB | RAMD |
| : | : | : | : | | | | |
| 01 | 00 | 00 | 00 | RAMC | RAMA | RAMB\hat{ }RAMP1 | RAMD\hat{ }RAMP2\hat{ }RAM4\hat{ }RAMP5 |
| | | | | | | = B\hat{ }(A\hat{ }B) | = D\hat{ }(C\hat{ }D)\hat{ }(B\hat{ }D)\hat{ }(A\hat{ }B\hat{ }C\hat{ }D) |
| | | | | | | = A | = A |
| : | : | : | : | | | | |
| 11 | 11 | 11 | 11 | RAMD | RAMC\hat{ }RAMP2 | RAMB\hat{ }RAMP4 | RAMA\hat{ }RAMP1\hat{ }RAM3\hat{ }RAMP5 |
| | | | | | = C\hat{ }(C\hat{ }D) | = B\hat{ }(B\hat{ }D) | = A\hat{ }(A\hat{ }B)\hat{ }(A\hat{ }C)\hat{ }(A\hat{ }B\hat{ }C\hat{ }D) |
| | | | | | = D | = D | = D |

In some embodiments, techniques implementing parity with sub-words as described and techniques implementing parity with sequential write operations as described are used to build multi-port memory with a high read port count. In these implementations, the memories are capable of performing both sequential write operations and retrieving sub-words from memory.

It should be noted that the configuration described with reference to FIG. 8 is provided by way of example only and is not meant to limit the present disclosure. For example, in embodiments of the disclosure, one or more of the memories 700 is implemented as a memory 100 (FIG. 1), a memory 200 (FIG. 2), a memory 300 (FIG. 3), a memory 400 (FIG. 4), a memory 700 (FIG. 7), and so forth, where one or more of the memories 100, 200, 300, 400, or 700 includes one or more parity registers. Further, while FIG. 8 illustrates first, second, and third memories 700, it should be noted that more than three memories can be provided. For example, in some implementations, five (5) memories 700 (e.g., with one memory 700 configured as parity) are provided (e.g., in the manner of memory 100 of FIG. 1). In other embodiments, eight (8) memories 700 (e.g., with four memories 700 configured as parity) are provided (e.g., in the manner of memory 200 of FIG. 2). In still further embodiments, nine (9) memories 700 (e.g., with five memories 700 configured as parity are provided (e.g., in the manner of memory 300 of FIG. 3).

Referring now to FIG. 9, a memory 900 with two or more memory arrays (e.g., memory arrays 902 and 904) is described. In embodiments, one or more memories 100, 200, 300, 400, 500, 600, 700, and 800 are used to construct a memory array 902 or 904. The memory 900 also includes write decoding logic module 906, read multiplexer 908, and read decoding logic module 910. In embodiments of the disclosure, the memory 900 is used with a networking system. For example, one of the memory arrays 902 and 904 is operated in a write configuration, and another of the memory arrays 902 and 904 is operated in a read configuration. In the present example, write decoding logic module 910 is operatively coupled with memory array 902, and read multiplexer 908 and read decoding logic module 910 are coupled with memory array 904. It should be noted that this configuration allows simultaneous read and write operations to the memory arrays 902 and 904, without requiring separate read and write decoding logic for each of the memory arrays 902 and 904. This configuration eliminates inactive logic circuitry that would otherwise be present with a typical n-port memory.

It should be noted that while the present disclosure describes single-port memory modules as a basic building block of some of the various memory configurations discussed herein, this configuration is provided by way of example only and is not meant to be limiting of the present disclosure. Thus, in other configurations, multi-port memory is used as a building block to construct one or more of the memories described herein. For example, a memory furnishing two read ports, three read ports, more than three read ports, and so forth can be used as a building block for one or more of the memories 100, 200, 300, 400, 500, 600, 700, 800, and 900.

Referring to FIG. 10, a system 1000 includes a controller 1002 operatively coupled with a memory 1010. The memory 1010 can be implemented using one or more memories 100, 200, 300, 400, 500, 600, 700, 800, and 900 as described. A controller 1002, including some or all of its components, can operate under computer control. For example, a processor 1004 can be included with or in a controller 1002 to control the components and functions of systems 1000 described herein using software, firmware, hardware (e.g., fixed logic circuitry), manual processing, or a combination thereof. The terms “controller,” “functionality,” “service,” and “logic” as used herein generally represent software, firmware, hardware, or a combination of software, firmware, or hardware in conjunction with controlling the systems 1000. In the case of a software implementation, the module, functionality, or logic represents program code that performs specified tasks when executed on a processor (e.g., central processing unit (CPU) or CPUs). The program code can be stored in one or more computer-readable memory devices (e.g., internal memory and/or one or more tangible media), and so on. The structures, functions, approaches, and techniques described herein can be implemented on a variety of commercial computing platforms having a variety of processors.

A processor 1004 provides processing functionality for the controller 1002 and can include any number of processors, micro-controllers, or other processing systems, and resident or external memory for storing data and other information accessed or generated by the system 1000. The processor 1004 can execute one or more software programs that implement techniques described herein. The processor 1004 is not limited by the materials from which it is formed or the processing mechanisms employed therein and, as such, can be implemented via semiconductor(s) and/or transistors (e.g., using electronic integrated circuit (IC) components), and so forth.

The controller 1002 includes a communications interface 1006. The communications interface 1006 is operatively configured to communicate with components of the system 1000. For example, the communications interface 1006 can be configured to transmit data for storage in the system 1000, retrieve data from storage in the system 1000, and so forth. The communications interface 1006 is also communicatively coupled with the processor 1004 to facilitate data transfer between components of the system 1000 and the processor 1004 (e.g., for communicating inputs to the processor 1004 received from a device communicatively coupled with the system 1000). It should be noted that while the communications interface 1006 is described as a component of a system 1000, one or more components of the communications interface 1006 can be implemented as external components communicatively coupled to the system 1000 via a wired and/or wireless connection.

The communications interface 1006 and/or the processor 1004 can be configured to communicate with a variety of different networks including, but not necessarily limited to: a wide-area cellular telephone network, such as a 3G cellular network, a 4G cellular network, or a global system for mobile communications (GSM) network; a wireless computer communications network, such as a WiFi network (e.g., a wireless local area network (WLAN) operated using IEEE 802.11 network standards); an internet; the Internet; a wide area network (WAN); a local area network (LAN); a personal area network (PAN) (e.g., a wireless personal area network (WPAN) operated using IEEE 802.15 network standards); a public telephone network; an extranet; an intranet; and so on. However, this list is provided by way of example only and is not meant to be restrictive of the present disclosure. Further, the communications interface 1006 can be configured to communicate with a single network or multiple networks across different access points.

The controller 1002 also includes a memory 1008. The memory 1008 is an example of tangible, computer-readable storage medium that provides storage functionality to store various data associated with operation of the controller 1002, such as software programs and/or code segments, or other data to instruct the processor 1004, and possibly other components of the controller 1002, to perform the functionality described herein. Thus, the memory 1008 can store data, such as a program of instructions for operating the controller 1002 (including its components), and so forth. It should be noted that while a single memory 1008 is described, a wide variety of types and combinations of memory (e.g., tangible, non-transitory memory) can be employed. The memory 1008 can be integral with the processor 1004, can comprise stand-alone memory, or can be a combination of both. The memory 1008 can include, but is not necessarily limited to: removable and non-removable memory components, such as random-access memory (RAM), read-only memory (ROM), flash memory (e.g., a secure digital (SD) memory card, a mini-SD memory card, and/or a micro-SD memory card), magnetic memory, optical memory, universal serial bus (USB) memory devices, hard disk memory, external memory, and so forth.

Generally, any of the functions described herein can be implemented using hardware (e.g., fixed logic circuitry such as integrated circuits), software, firmware, manual processing, or a combination thereof. Thus, the blocks discussed in the above disclosure generally represent hardware (e.g., fixed logic circuitry such as integrated circuits), software, firmware, or a combination thereof. In embodiments of the disclosure that manifest in the form of integrated circuits, the various blocks discussed in the above disclosure can be implemented as integrated circuits along with other functionality. Such integrated circuits can include all of the functions of a given block, system, or circuit, or a portion of the functions of the block, system or circuit. Further, elements of the blocks, systems, or circuits can be implemented across multiple integrated circuits. Such integrated circuits can comprise various integrated circuits including, but not necessarily limited to: a system on a chip (SoC), a monolithic integrated circuit, a flip chip integrated circuit, a multichip module integrated circuit, and/or a mixed signal integrated circuit. In embodiments of the disclosure that manifest in the form of software, the various blocks discussed in the above disclosure represent executable instructions (e.g., program code) that perform specified tasks when executed on a processor. These executable instructions can be stored in one or more tangible computer readable media. In some such embodiments, the entire system, block or circuit can be implemented using its software or firmware equivalent. In some embodiments, one part of a given system, block or circuit can be implemented in software or firmware, while other parts are implemented in hardware.

Although embodiments of the disclosure have been described in language specific to structural features and/or methodological acts, it is to be understood that the subject matter defined in the appended claims is not necessarily limited to the specific embodiments described. Although various configurations are discussed, the apparatus, systems, subsystems, components and so forth can be constructed in a variety of ways without departing from teachings of this disclosure. Rather, the specific features and acts are disclosed as embodiments of implementing the claims.

What is claimed is:

1. A memory operative to receive a multi-port read request and furnish data associated with a first port, a second port, and a third port in response to the multi-port read request, the memory comprising:
a first memory comprising a first memory module, a second memory module, and a third memory module configured as a first parity module;
a second memory comprising a fourth memory module, a fifth memory module, and a sixth memory module configured as a second parity module;
a third memory comprising a seventh memory module, an eighth memory module, and a ninth memory module configured as a third parity module; and
a controller operatively coupled with the first memory, the second memory, and the third memory and configured to receive a multi-port read request associated with first data stored at a first memory address associated with the first port, second data stored at a second memory address associated with the second port, and third data stored at a third memory address associated with the third port, wherein, when the first memory address, the second memory address, and the third memory address are associated with the first memory module, the controller is operatively configured to retrieve the first data from the first memory module, reconstruct the second data using data from the second memory module and the first parity module, reconstruct the third data using data from the fourth memory module and the seventh memory module, and provide the first data, the second data, and the third data in response to the multi-port read request.

2. The memory as recited in claim 1, wherein the multi-port read request is further associated with fourth data stored at a fourth memory address associated with a fourth port, and the controller is operatively configured to reconstruct the fourth data using data from the fifth memory module, the second parity module, the eighth memory module, and the third parity module when the first memory address, the second memory address, the third memory address, and the fourth memory address are associated with the first memory module.

3. The memory as recited in claim 1, wherein at least one of the first memory module, the second memory module, the third memory module, the fourth memory module, the fifth memory module, the sixth memory module, the seventh memory module, the eighth memory module, or the ninth memory module comprises a single-port memory module.

4. The memory as recited in claim 1, wherein the first memory further comprises a tenth memory module and an eleventh memory module, and the first parity module is associated with the first memory module, the second memory module, the tenth memory module, and the eleventh memory module.

5. The memory as recited in claim 1, wherein the first memory further comprises a tenth memory module, an eleventh memory module, a twelfth memory module configured as a fourth parity module, a thirteenth memory module configured as a fifth parity module, and a fourteenth memory module configured as a sixth parity module, the first parity module is associated with the first memory module and the second memory module, the fourth parity module is associated with the tenth memory module and the eleventh memory module, the fifth parity module is associated with the first memory module and the tenth memory module, and the sixth parity module is associated with the second memory module and the eleventh memory module.

6. The memory as recited in claim 1, wherein the first memory further comprises a tenth memory module, an eleventh memory module, a twelfth memory module configured as a fourth parity module, a thirteenth memory module configured as a fifth parity module, a fourteenth memory module configured as a sixth parity module, and a fifteenth memory module configured as a seventh parity module, the first parity module is associated with the first memory module and the second memory module, the fourth parity module is associated with the tenth memory module and the eleventh memory module, the fifth parity module is associated with the first memory module and the tenth memory module, the sixth parity module is associated with the second memory module and the eleventh memory module, and the seventh parity module is associated with the first memory module, the second memory module, the tenth memory module, and the eleventh memory module.

7. The memory as recited in claim 1, wherein the memory is included in an array of memories.

8. The memory as recited in claim 1, wherein the memory is fabricated in an integrated circuit.

9. A tangible computer-readable storage medium having computer executable instructions for receiving a multi-port read request and furnishing data associated with a first port, a second port, and a third port in response to the multi-port read request, the computer executable instructions comprising:
receiving a multi-port read request for retrieval of data stored in a first memory comprising a first memory module, a second memory module, and a third memory module configured as a first parity module; a second memory comprising a fourth memory module, a fifth memory module, and a sixth memory module configured as a second parity module; and a third memory comprising a seventh memory module, an eighth memory module, and a ninth memory module configured as a third parity module, the multi-port read request associated with first data stored at a first memory address associated with the first port, second data stored at a second memory address associated with the second port, and third data stored at a third memory address associated with the third port;
when the first memory address, the second memory address, and the third memory address are associated with the first memory module, retrieving the first data from the first memory module, reconstructing the second data using data from the second memory module and the first parity module, and reconstructing the third data using data from the fourth memory module and the seventh memory module; and
providing the first data, the second data, and the third data in response to the multi-port read request.

10. The tangible computer-readable storage medium as recited in claim 9, wherein the multi-port read request is further associated with fourth data stored at a fourth memory address associated with a fourth port, and the computer executable instructions further comprise:
when the first memory address, the second memory address, and the third memory address are associated with the first memory module, reconstructing the fourth data using data from the fifth memory module, the second parity module, the eighth memory module, and the third parity module; and
providing the fourth data in response to the multi-port read request.

11. The tangible computer-readable storage medium as recited in claim 9, wherein at least one of the first memory module, the second memory module, the third memory module, the fourth memory module, the fifth memory module, or the sixth memory module comprises a single-port memory module.

12. The tangible computer-readable storage medium as recited in claim 9, wherein the first memory further comprises a tenth memory module and an eleventh memory module, and the first parity module is associated with the first memory module, the second memory module, the tenth memory module, and the eleventh memory module.

13. The tangible computer-readable storage medium as recited in claim 9, wherein the first memory further comprises a tenth memory module, an eleventh memory module, a twelfth memory module configured as a fourth parity module, a thirteenth memory module configured as a fifth parity module, and a fourteenth memory module configured as a sixth parity module, the first parity module is associated with the first memory module and the second memory module, the fourth parity module is associated with the tenth memory module and the eleventh memory module, the fifth parity module is associated with the first memory module and the tenth memory module, and the sixth parity module is associated with the second memory module and the eleventh memory module.

14. The tangible computer-readable storage medium as recited in claim 9, wherein the first memory further comprises a tenth memory module, an eleventh memory module, a twelfth memory module configured as a fourth parity module, a thirteenth memory module configured as a fifth parity module, a fourteenth memory module configured as a sixth parity module, and a fifteenth memory module configured as a seventh parity module, the first parity module is associated with the first memory module and the second memory module, the fourth parity module is associated with the tenth memory module and the eleventh memory module, the fifth parity module is associated with the first memory module and the tenth memory module, the sixth parity module is associated with the second memory module and the eleventh memory module, and the seventh parity module is associated with the first memory module, the second memory module, the tenth memory module, and the eleventh memory module.

15. The tangible computer-readable storage medium as recited in claim 9, wherein the first memory, the second memory, and the third memory are included in a first memory array, and the first memory array is included in a memory comprising an array of first memory arrays.

16. A memory operative to receive a multi-port read request and furnish data associated with a first port, a second port, and a third port in response to the multi-port read request, the memory comprising:
a first memory comprising a first memory module, a second memory module, a third memory module configured as a first parity module, and a first parity register;
a second memory comprising a fourth memory module, a fifth memory module, a sixth memory module configured as a second parity module, and a second parity register;
a third memory comprising a seventh memory module, an eighth memory module, a ninth memory module configured as a third parity module, and a third parity register;
a fourth parity register; and
a controller operatively coupled with the first memory, the second memory, the third memory, and the fourth parity register, and configured to receive a multi-port read request associated with first data stored at a first memory address associated with the first port, second data stored at a second memory address associated with the second port, and third data stored at a third memory address associated with the third port, wherein, when the first memory address, the second memory address, and the third memory address are associated with the first memory module, the controller is operatively configured to retrieve the first data from the first memory module, reconstruct the second data using data from the second memory module and the first parity module, reconstruct the third data using data from the fourth memory module and the seventh memory module, and provide the first data, the second data, and the third data in response to the multi-port read request.

17. The memory as recited in claim 16, wherein the multi-port read request is further associated with fourth data stored at a fourth memory address associated with a fourth port, and the controller is operatively configured to reconstruct the fourth data using data from the fifth memory module, the second parity module, the eighth memory module, and the third parity module when the first memory address, the second memory address, the third memory address, and the fourth memory address are associated with the first memory module.

18. The memory as recited in claim 16, wherein at least one of the first memory module, the second memory module, the third memory module, the fourth memory module, the fifth memory module, the sixth memory module, the seventh memory module, the eighth memory module, or the ninth memory module comprises a single-port memory module.

19. The memory as recited in claim 16, wherein the first memory further comprises a tenth memory module and an eleventh memory module, and the first parity module is associated with the first memory module, the second memory module, the tenth memory module, and the eleventh memory module.

20. The memory as recited in claim 16, wherein the first memory further comprises a tenth memory module, an eleventh memory module, a twelfth memory module configured as a fourth parity module, a thirteenth memory module configured as a fifth parity module, and a fourteenth memory module configured as a sixth parity module, the first parity module is associated with the first memory module and the second memory module, the fourth parity module is associated with the tenth memory module and the eleventh memory module, the fifth parity module is associated with the first memory module and the tenth memory module, and the sixth parity module is associated with the second memory module and the eleventh memory module.
